(19) United States
(12) Patent Application Publication
(10) Pub. No.: US 2026/0353786 A1
(43) Pub. Date: Nov. 5, 2026

(54) GATE ELECTRODE GAP-FILLING IN STACKING TRANSISTORS AND STRUCTURES THEREOF

(71) Applicant: Taiwan Semiconductor Manufacturing Co., Ltd., Hsinchu (TW)

(72) Inventors: Kai-Chieh Yang, New Taipei City (TW); Chun-Da Liao, Taipei City (TW); Chun-Yu Liu, New Taipei City (TW); Wei-Yen Woon, Hsinchu County (TW); Szuya Liao, Zhubei (TW)

(21) Appl. No.: 19/737,737

(22) Filed: Jul. 10, 2026

Related U.S. Application Data
(63) Continuation of application No. 19/176,825, filed on Apr. 11, 2025.
(60) Provisional application No. 63/719,180, filed on Nov. 12, 2024.

(51) Int. Cl. H10D 84/85; H10D 30/00; H10D 30/01; H10D 62/10; H10D 64/66; H10D 84/01

(52) U.S. Cl. CPC H10D 84/851; H10D 30/019; H10D 30/502; H10D 62/121; H10D 64/667; H10D 64/669; H10D 84/0177; H10D 84/0179; H10D 84/856

(57) ABSTRACT

A method includes forming a lower source/drain region and an upper source/drain region adjacent to a multi-layer stack, the multi-layer stack comprising dummy nanostructures that are alternatingly stacked with semiconductor nanostructures, the semiconductor nanostructures comprising lower semiconductor nanostructures and upper semiconductor nanostructures; removing the dummy nanostructures; forming first gate dielectrics around the lower semiconductor nanostructures and second gate dielectrics around the upper semiconductor nanostructures; forming a first work function metal layer over the first gate dielectrics and the second gate dielectrics; forming a first metal over the first work function metal layer; performing a first etch on the first metal to expose the first work function metal layer; performing a second etch on the first work function metal layer to expose the second gate dielectrics; forming a second work function metal layer over the second gate dielectrics; and forming a second metal over the second work function metal layer.

### PRIORITY CLAIM AND CROSS-REFERENCE

This application is a continuation of U.S. Patent Application No. 19/176,825 filed on Apr. 11, 2025, which application claims the benefit of the following provisionally filed U.S. Patent Application No. 63/719,180, filed on Nov. 12, 2024, and which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stacking transistor, in accordance with some embodiments.

FIGS. 2, 3A, 3B, 4A, 4B, 5A, 5B, 6A, 6B, 7A, 7B, 8A, 8B, 9A, 9B, 10A, 10B, 11A and 11B, are views of intermediate stages in the manufacturing of stacking transistors, in accordance with some embodiments.

FIGS. 12A, 12B, 13A, 13B, 13C, 13D, 14A, 14B, 14C, 14D, 15A, 15B, 15C and 15D, are views of intermediate stages in the manufacturing of stacking transistors, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor structure including an upper transistor and a lower transistor that are vertically stacked and the method of forming the same are provided. After forming source/drain regions of the lower transistor and the upper transistor adjacent to lower and upper channel regions, a gate replacement process is performed to form a gate stack comprising gate dielectrics, a lower gate electrode, and an upper gate electrode. For example, dummy material is removed to form a recess comprising a lower recess and an upper recess, and the gate dielectrics are formed over the channel regions in the lower recess and the upper recess. A lower work function metal layer is then formed over the gate dielectrics in the lower recess and the upper recess, and a lower gap-filling metal is formed over the lower work function metal in the lower recess and the upper recess. To form a lower gate electrode in the lower recess, the lower gap-filling metal is removed from the upper recess, and then the lower work function metal layer is removed from the upper recess. To form an upper gate electrode in the upper recess, an upper work function metal layer and an upper gap-filling metal are formed over the lower gate electrode. Embodiment devices may be formed with increased yield due to greater control over the gate replacement process, and embodiment devices may provide improved performance and reliability.

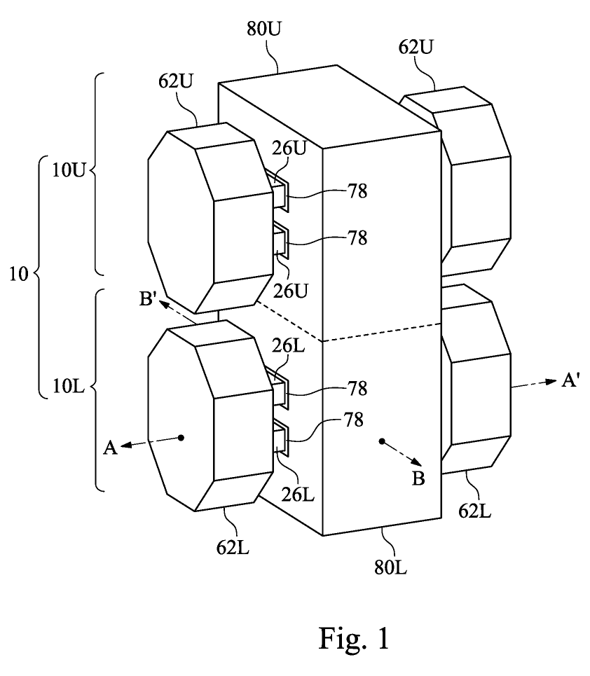

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A' is a vertical cross-section that is parallel to a longitudinal axis of the semiconductor nanostructures 26 of a stacking transistor and in a direction of, for example, a current flow between the source/drain regions 62 of the stacking transistor. Cross-section B-B' is a vertical cross-section that is perpendicular to cross-section A-A' and along a longitudinal axis of a gate electrode 80 of the CFET. Subsequent figures may refer to these reference cross-sections for clarity.

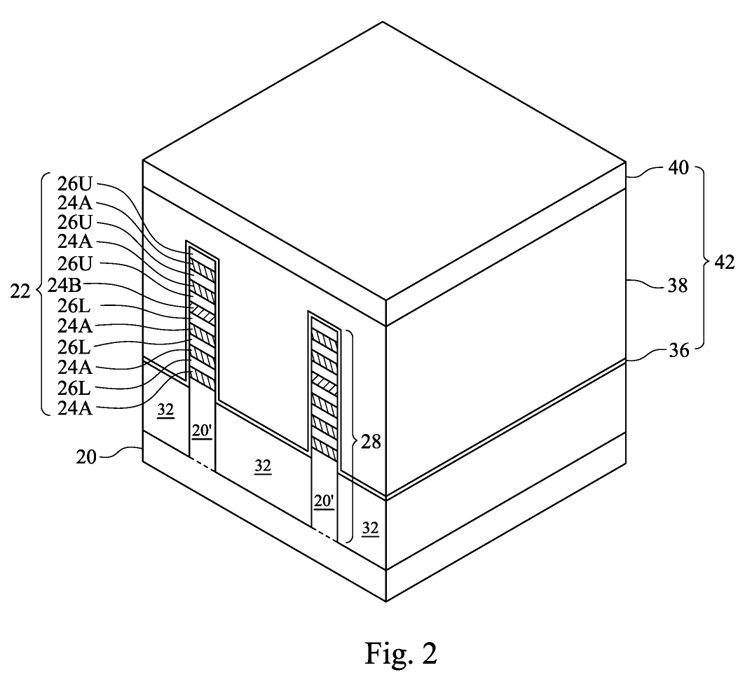

FIGS. 2 through 15D illustrate the cross-sectional views of intermediate stages in the formation of stacking transistors (as schematically represented in FIG. 1) in accordance with some embodiments. In subsequent discussion, unless specified otherwise, the figures having digits followed by letter “A” or letter “C” illustrate the vertical cross-sectional views along a similar cross-section as vertical reference cross-section A-A' in FIG. 1. The figures having digits followed by letter “B” or letter “D” illustrate the vertical cross-sectional views along a similar cross-section as the vertical reference cross-section B-B' in FIG. 1.

In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20’ (patterned portions of the semiconductor substrate 20, also referred to as semiconductor fins 20') and a multi-layer stack 22. The stacked components of the multi-layer stack 22 are referred to as nanostructures hereinafter. Specifically, the multi-layer stack 22 includes dummy nanostructures 24A, one or more dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B are formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructures 24 may be selectively removed in subsequent process steps without significantly removing the semiconductor nanostructures 26. In some embodiments, the dummy nanostructures 24A are formed of or comprise silicon germanium, the semiconductor nanostructures 26 are formed of silicon, and the dummy nanostructures 24B may be formed of germanium or silicon germanium with a higher germanium atomic percentage than the dummy nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20', the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, isolation regions 32 such as shallow trench isolation (STI) regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. The dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 may be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

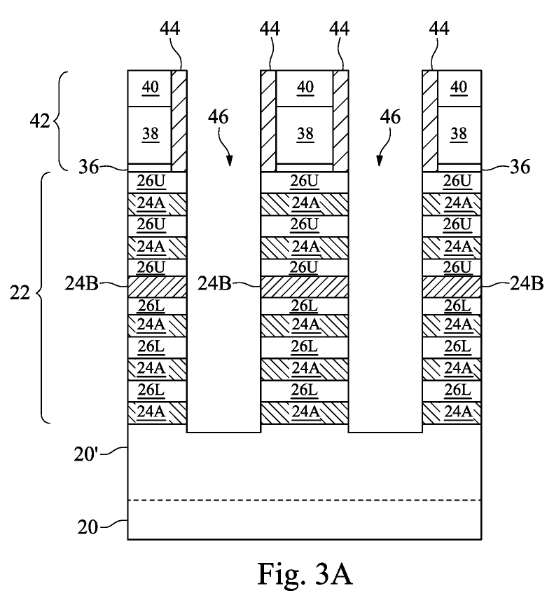

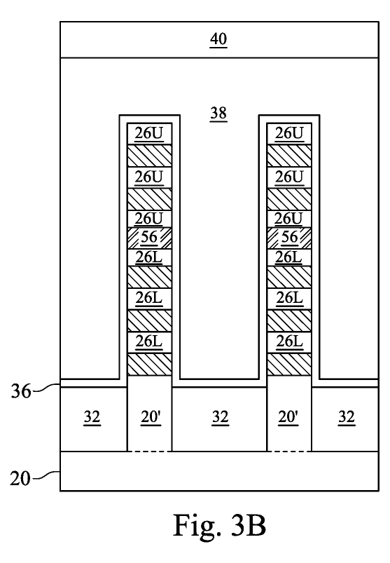

In FIGS. 3A and 3B, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20’. Bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a desired depth.

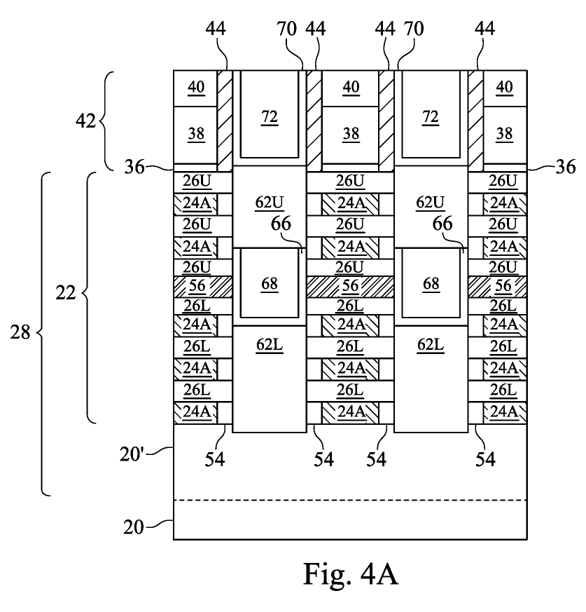

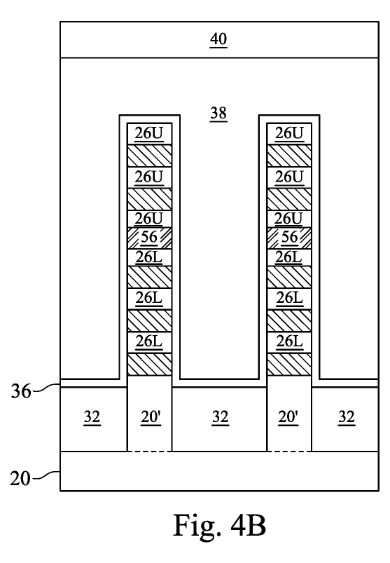

In FIGS. 4A and 4B, inner spacers 54 and dielectric isolation layers 56 are formed. Forming the inner spacers 54 and the dielectric isolation layers 56 may include an etching process that laterally etches the dummy nanostructures 24A and removes the dummy nanostructures 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A.

In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 wrap around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

The inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. The dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs. Note that the dielectric isolation layers 56 may also be referred to as dielectric nanostructures, isolation nanostructures, dielectric isolation sheets, or variants thereof.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As further illustrated by FIGS. 4A and 4B, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 40 (if present) or the dummy gates 38 are substantially coplanar (within process variations). Accordingly, the top surfaces of the masks 40 (if present) or the dummy gates 38 are exposed through the second ILD 124. In the illustrated embodiment, the masks 40 remain after the removal process. In other embodiments, the masks 40 are removed such that the top surfaces of the dummy gates 38 are exposed through the first ILD 68.

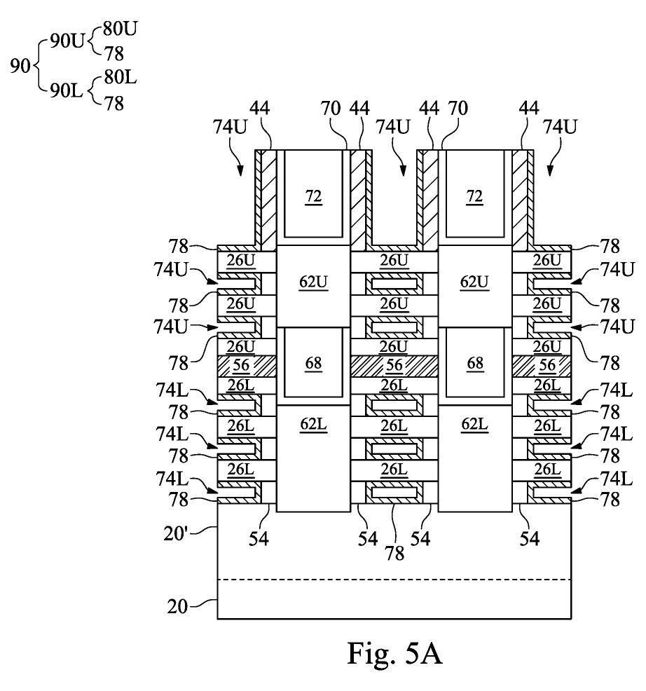

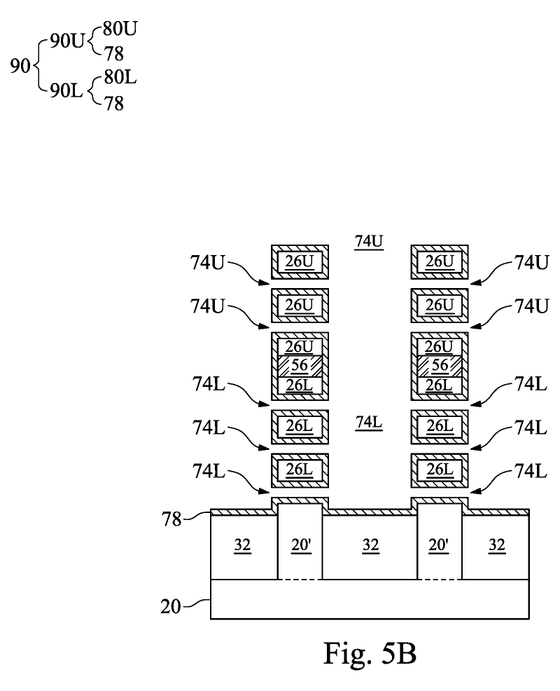

FIGS. 5A through 10B illustrate a replacement gate process to replace the dummy gate stacks 42 and the dummy nanostructures 24A with gate stacks 90. Each gate stack 90 includes gate dielectrics 78 and gate electrodes 80 (e.g., a lower gate electrode 80L and an upper gate electrode 80U), and each gate electrode 80 includes a work function metal layer 82 and a gap-filling metal 84 (e.g., a fill metal structure). The replacement gate process includes first removing the dummy gate stacks 42 and the remaining portions of the dummy nanostructures 24A. For example, the dummy gate stacks 42 are removed, gate dielectrics 78 are deposited, lower gate electrodes 80L are formed over the gate dielectrics 78 around the lower semiconductor nanostructures 26L, and upper gate electrodes 80U are formed over the gate dielectrics 78 around the upper semiconductor nanostructures 26U. As discussed in greater detail below, the lower gate electrodes 80L may comprise a lower work function metal layer 82L and a lower gap-filling metal 84L, and the upper gate electrode 80U may comprise an upper work function metal layer 82U and an upper gap-filling metal 84U.

In accordance with some embodiments, the gate electrodes 80 are formed to be seamless, such as utilizing seamless gap-filling metals 84. In particular, the lower gate electrode 80L may such that the lower work function metal layer 82L comprises a material which may be used as a gap-filling metal in other transistors and the lower gap-filling metal 84L comprises a material which can be deposited in a seam-free manner. As a result, after deposition, the lower work function metal layer 82L and the lower gap-filling metal 84L may be etched to a desired level with improved control and yield. The upper gate electrode 80U may then be formed thereover also with improved control and yield. Although the embodiments may be described herein with respect to the lower transistor being a p-type nanostructure-FET and the upper transistor being an n-type nanostructure-FET, the embodiments may include any combinations of device types as appropriate (e.g., p-type and n-type, n-type and p-type, both n-type, and/or both p-type). Moreover, a p-type nanostructure-FET will include a gate electrode 80 comprising a p-type work function metal layer 82 and a p-type gap-filling metal 84, and an n-type nanostructure-FET will include a gate electrode 80 comprising an n-type work function metal layer 82 and an n-type gap-filling metal 84.

In FIGS. 5A and 5B, the dummy gate stacks 42 are removed in one or more etching processes so that recesses 74 are defined between the gate spacers 44 and the upper portions of the semiconductor strips 28 are exposed. The remaining portions of the dummy nanostructures 24A are then removed through etching, so that the recesses 74 extend between the semiconductor nanostructures 26. As illustrated, the recesses 74 may include upper recesses 74U adjacent to and between the upper semiconductor nanostructures 26U and lower recesses 74L adjacent to and between the lower semiconductor nanostructures 26L. Note that an invisible boundary between the upper recesses 74U and the lower recesses 74L may be considered as being located laterally adjacent to the dielectric isolation layer 56 which separates the upper semiconductor nanostructures 26U from the lower semiconductor nanostructures 26L. In the etching process, the material of the dummy nanostructures 24A is etched at a faster rate than the materials of the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses 74 between the gate spacers 44 and on the exposed semiconductor nanostructures 26. The gate dielectrics 78 are conformally formed on the exposed surfaces of the recesses 74 (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. As illustrated, one or more layers of the gate dielectrics 78 may form a continuous ring or loop around an uppermost nanostructure of the lower semiconductor nanostructures 26L, the one of the dielectric isolation layers 56, and a lowermost nanostructure of the upper semiconductor nanostructures 26U. Specifically, the gate dielectrics 78 may be formed on the top surfaces of the fins 20'; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

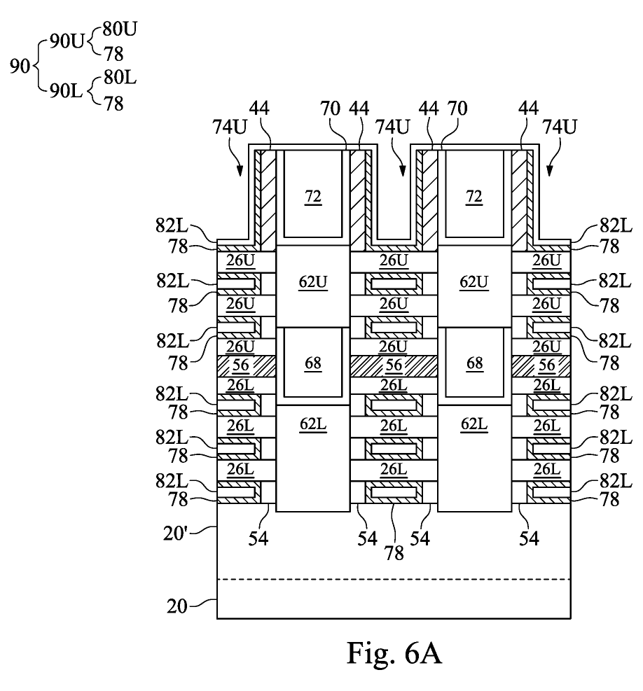

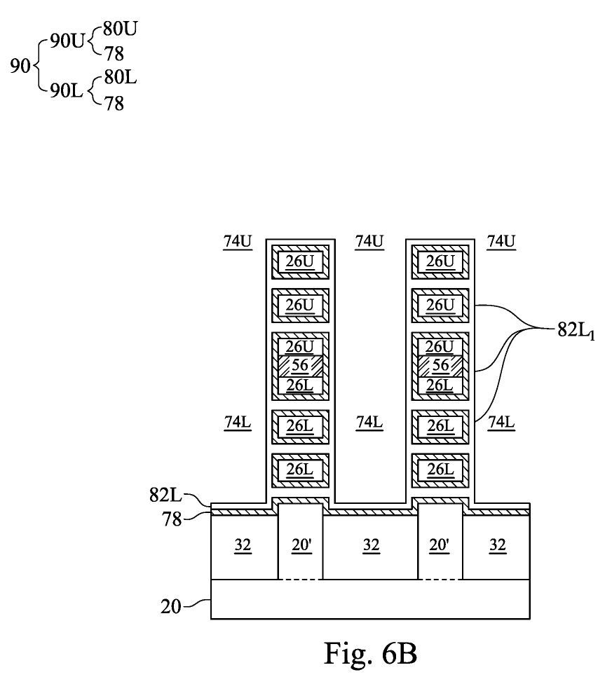

FIGS. 6A through 10B illustrate formation of gate electrodes 80 over the gate dielectrics 78. In particular, lower gate electrodes 80L are formed on the gate dielectrics 78 around the lower semiconductor nanostructures 26L, and upper gate electrodes 80U on the gate dielectrics 78 around the upper semiconductor nanostructures 26U. For example, the lower gate electrodes 80L wrap around the lower semiconductor nanostructures 26L, and the upper gate electrodes 80U wrap around the upper semiconductor nanostructure 26U. The gate electrodes 80 may be formed of various metal-containing materials such as tungsten, titanium, titanium nitride, tantalum, tantalum nitride, tantalum carbide, aluminum, ruthenium, cobalt, combinations thereof, multi-layers thereof, or the like. Although two-layered gate electrodes 80 are illustrated, each of the upper and lower gate electrodes 80U and 80L may include any number of work function tuning layers (e.g., work function metal (WFM) layers), any number of barrier layers, any number of glue layers, and a fill material. The illustrated embodiments show the lower gate electrodes 80L as comprising lower work function metal layer 82L and lower gap-filling metal 84L and the upper gate electrodes 80U as comprising upper work function metal layer 82U and upper gap-filling metal 84U.

Each type of the gate electrodes 80 is formed of materials that are suitable for the device type of the particular nanostructure-FETs. For example, the work function metal layers 82 of the respective gate electrodes 80 may include one or more material(s) that are suitable for the device type of the particular nanostructure-FETs. In some embodiments, the gate electrode 80 (e.g., the lower gate electrode 80L) may include a p-type work function tuning layer, which may be formed of titanium nitride, titanium aluminum, tantalum nitride, combinations thereof, or the like. In some embodiments, the gate electrode 80 (e.g., the upper gate electrode 80U) may include an n-type work function tuning layer, which may be formed of titanium aluminum, titanium aluminum carbide, tantalum aluminum, tantalum carbide, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

Referring to FIGS. 6A-9B, the lower gate electrodes 80L may be formed by conformally depositing the gate electrode layer(s) (e.g., the lower work function metal layer 82L and the lower gap-filling metal 84L) and then recessing the gate electrode layers. Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In FIGS. 6A and 6B, the lower work function metal layer 82L is deposited in the recesses 74 over the gate dielectrics 78 around the upper and lower semiconductor nanostructures 26U and 26L. The lower work function metal layer 82L may be conformally formed over the gate dielectrics 78 as well as any barrier layers and/or glue layers (not separately illustrated). The lower work function metal layer 82L may be formed of the same candidate materials and candidate processes as described above. In some embodiments, the lower work function metal layer 82L comprises titanium nitride and is deposited using ALD, CVD, the like, or any suitable conformal deposition process.

As illustrated, the lower work function metal layer 82L is deposited around both the lower semiconductor nanostructures 26L and the upper semiconductor nanostructures 26U. In addition, the lower work function metal layer 82L may be deposited with a sufficient thickness to fill the portions of the recesses 74 between adjacent semiconductor nanostructures 26. As illustrated, the lower work function metal layer 82L comprises a plurality of rings 82L₁ around the semiconductor nanostructures 26, wherein the rings are continuous with one another. In some embodiments, some space may remain in these portions of the recesses 74 between adjacent portions of the lower work function metal layer 82L. In such embodiments, the rings 82L₁ may be discrete portions (e.g., discontinuous with one another).

Note that although the lower work function metal layer 82L may comprise a metal (e.g., titanium nitride) that would be suitable as the lower gap-filling metal 84L, deposition is halted after depositing a conformal layer of the lower work function metal layer 82L to serve as the work function tuning layer for the lower gate electrode 80L. The lower gap-filling metal 84L is deposited using CVD with a different material (e.g., ruthenium and/or molybdenum) which can seamlessly fill the recesses 74 because this different material exhibits a bottom-up growth behavior. In comparison, titanium nitride deposited using ALD or CVD exhibits a conformal growth behavior, thereby making titanium nitride a suitable candidate for the lower work function metal layer 82L in the disclosed embodiments. Moreover, these combinations of materials and processes allow for the lower gate electrode 80L and the corresponding gate dielectrics 78 to have substantially same voltage thresholds and capacitance equivalent thicknesses as if the gate electrode 80 included titanium nitride formed by ALD as the gap-filling metal 84.

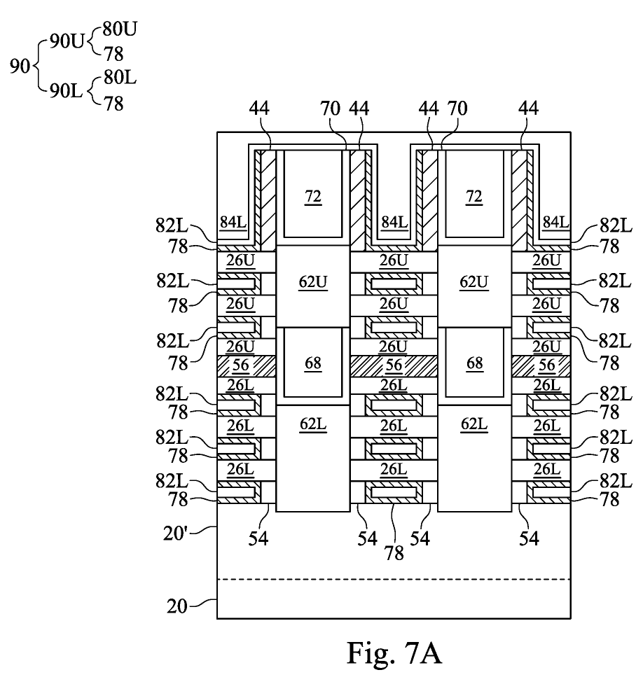

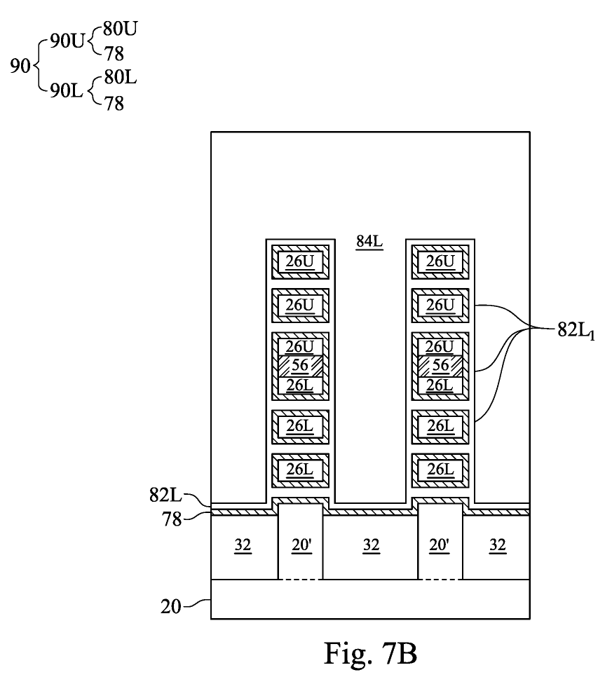

In FIGS. 7A and 7B, the lower gap-filling metal 84L is deposited in the recesses 74 over the lower work function metal layer 82L around the upper and lower semiconductor nanostructures 26U and 26L. The lower gap-filling metal 84L may fill remainders of the recesses 74 and be formed of the same candidate materials and candidate processes as described above. In some embodiments, the lower gap-filling metal 84L comprises ruthenium, molybdenum, or an alloy thereof. Optionally, the lower gap-filling metal 84L is first deposited using ALD to form a seed layer (not separately illustrated) and then using CVD to fill the remainders of the recesses 74. The CVD process is allows for the lower gap-filling metal 84L to grow at a faster rate than using the ALD process for an entirety of the growth. In some embodiments, the ALD process may be omitted and, instead, the CVD process is used to deposit the entirety of the lower gap-filling metal 84L over and around the lower work function metal layer 82L.

As discussed above, deposition of the lower gap-filling metal 84L may have a bottom-up growth behavior. As a result, the lower gap-filling metal 84L is free of a vertical seam that may otherwise form with materials (e.g., TiN) and processes (e.g., ALD) that exhibit a conformal growth behavior. The seamless profile of the lower gap-filling metal 84L ensures that subsequent etching of the lower gap-filling metal 84L will have greater control and may be performed at a faster rate. In addition, the growth of the lower gap-filling metal 84L occurs at a faster rate than, say, a conformal deposition of titanium nitride using ALD.

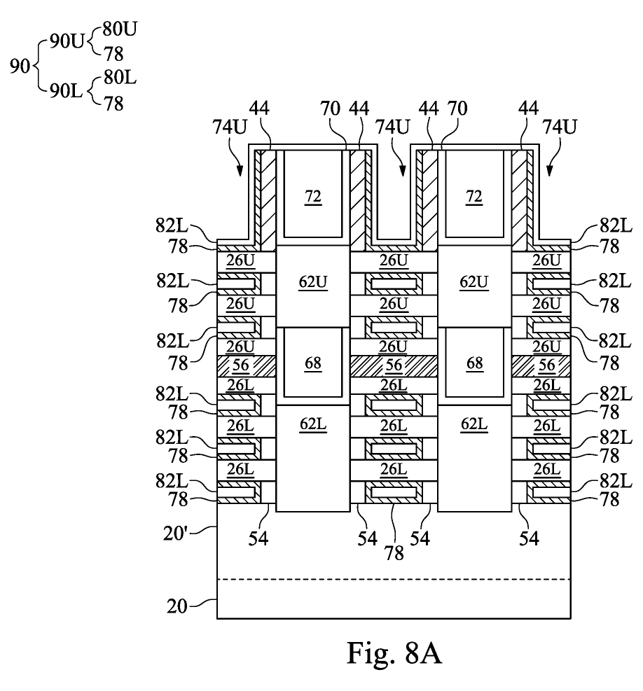

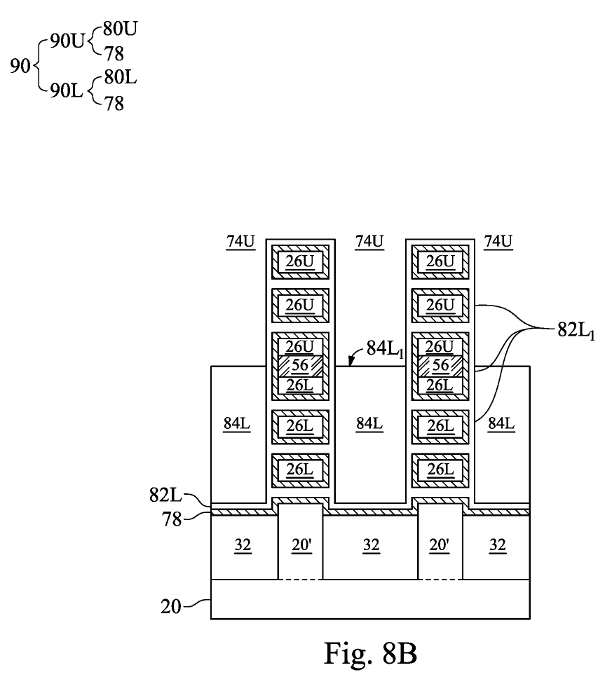

In FIGS. 8A and 8B, an etch process is performed on the lower gap-filling metal 84L to reopen the upper recesses 74U. In some embodiments, the etch process may include a dry etch process and may be selective to the material of the lower gap-filling metal 84L, so that the lower gap-filling metal 84L (e.g., comprising ruthenium and/or molybdenum) is etched at a faster rate than the lower work function metal layer 82L (e.g., comprising titanium nitride). As such, the lower work function metal layer 82L (e.g., located in the upper recess 74U) is exposed and serves as a hard mask to protect underlying features. In some embodiments, the etch process may include any suitable etchants such as a chlorine-based etchant (e.g., chlorine (Cl₂)) or a sulfur-based etchant (e.g., sulfur hexafluoride (SF₆), or the like.

As illustrated, the lower gap-filling metal 84L may be etched until an upper surface 84L₁ is laterally adjacent to the dielectric isolation layers 56. In particular, the lower gap-filling metal 84L is removed from the upper recess 74U while the lower recess 74L remains filled. As noted above, the etch process can be performed more quickly, with greater control (e.g., a flatter upper surface 84L₁), and at a higher yield due to the lower gap-filling metal 84L being seam-free.

In some embodiments (not specifically illustrated), isolation layers may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

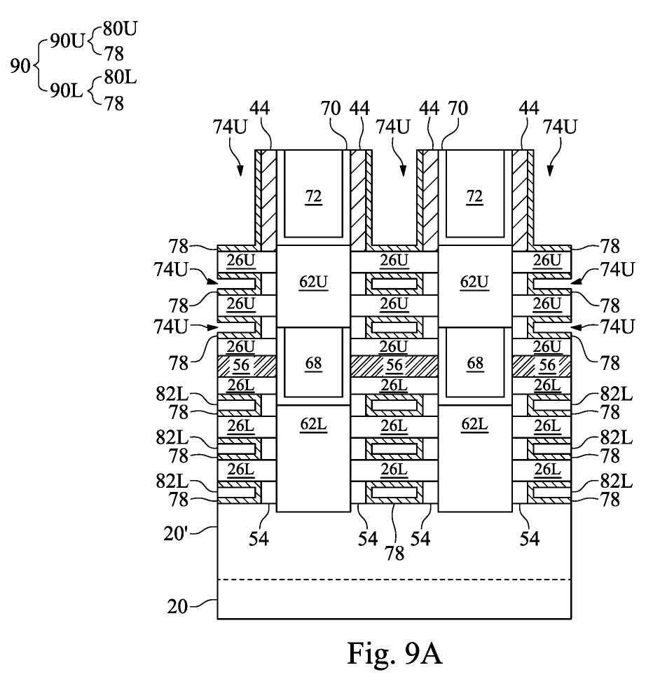

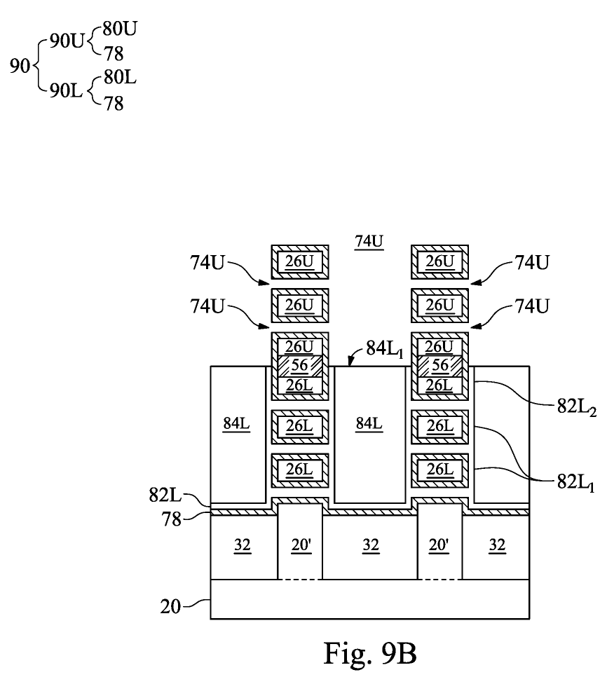

In FIGS. 9A and 9B, an etch process is performed on the lower work function metal layer 82L to expose the gate dielectrics 78 around the upper semiconductor nanostructure 26U. In some embodiments, the etch process may include a wet etch process and may be selective to the material of the lower work function metal layer 82L, so that the lower work function metal layer 82L (e.g., comprising titanium nitride) is etched at a faster rate than remaining portions of the lower gap-filling metal 84L (e.g., comprising ruthenium and/or molybdenum). As such, exposed portions of the lower gap-filling metal 84L remain substantially preserved. In some embodiments, the etch process may include any suitable etchants such as a chemical solution of hydrogen peroxide (H₂O₂) and ammonium hydroxide (NH₄OH).

As illustrated, after the etch process, the lower work function metal layer 82L still comprises a plurality of rings 82L₁ around the semiconductor nanostructures 26, wherein the rings 82L₁ are continuous with one another. In addition, some of the rings 82L₁may be converted to U-shaped portions 82L₂ after the etch process.

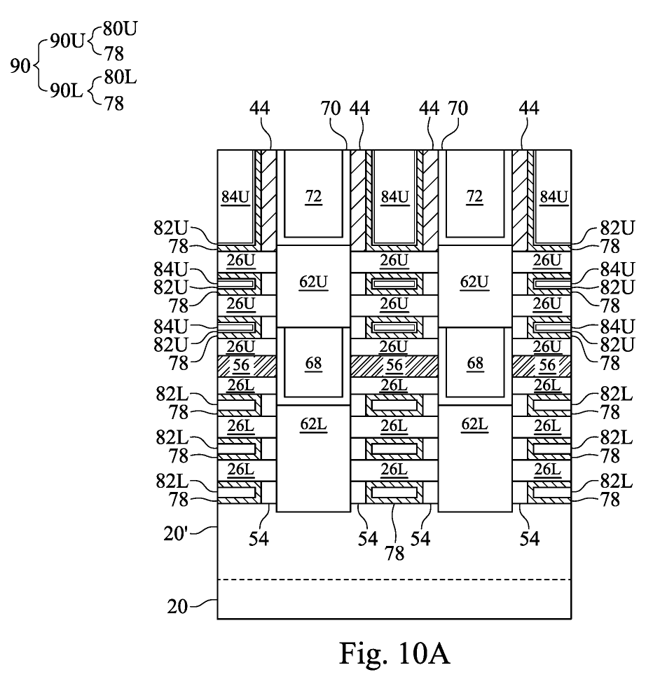

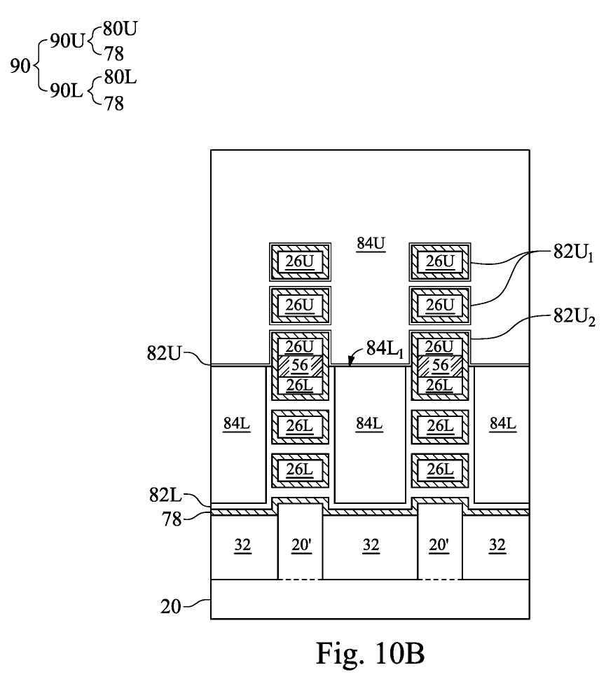

In FIGS. 10A and 10B, the upper gate electrodes 80U are formed in the upper recesses 74U, around the upper semiconductor nanostructures 26U, and over the etched lower gate electrodes 80L. As discussed above, the upper gate electrodes 80U include the upper work function metal layer 82U and the upper gap-filling metal 84U. For example, the lower gate electrodes 80L may be formed of materials that are suitable for a p-type nanostructure-FET (e.g., or an n-type nanostructure-FET), and the upper gate electrodes 80U are formed of materials that are suitable for an n-type nanostructure-FET (e.g., or a p-type nanostructure-FET).

The upper work function metal layer 82U may be formed of the same candidate materials and candidate processes as described above. In some embodiments, the upper work function metal layer 82U comprises titanium aluminum and is deposited using ALD, CVD, the like, or any suitable conformal deposition process.

The upper gap-filling metal 84U may fill remainders of the recesses 74 (e.g., the upper recesses 74U) and be formed of the same candidate materials and candidate processes as described above. In some embodiments, the upper gap-filling metal 84U comprises a metal different from ruthenium and molybdenum, such as titanium nitride. In addition, the upper gap-filling metal 84U may be deposited using CVD.

In accordance with some embodiments, the upper work function metal layer 82U is formed with a lesser thickness than that of the lower work function metal layer 82L. As illustrated, after deposition of the upper work function metal layer 82U, the upper recesses 74U may still include spaces which extend between adjacent upper semiconductor nanostructures 26U, and portions of the upper gap-filling metal 84U may fill remainders of these spaces. For example, in the cross-section illustrated in FIG. 10B, the upper work function metal layer 82U comprises discrete portions around each of the upper semiconductor nanostructures 26U, wherein some of the discrete portions are rings 82U₁ around respective upper semiconductor nanostructures 26U. Some of the discrete portions may are U-shaped portions 82U₂ (e.g., downward facing) around a lowermost nanostructure of the upper semiconductor nanostructures 26U and extend along the lower gate electrode 80L.

In some embodiments (not specifically illustrated), the upper work function metal layer 82U may have substantially the same thickness as the lower work function metal layer 82L and/or substantially fill the spaces of the upper recesses 74U which extend between adjacent upper semiconductor nanostructures 26U. In such embodiments, the rings 82U₁ of the upper work function metal layer 82U around some of the upper semiconductor nanostructures 26U would be continuous with one another as well as with the portion which has a downward U-shape (e.g., U-shaped portion 82U₂) around the lowermost nanostructure of the upper semiconductor nanostructures 26U. As such, the spaces between adjacent upper semiconductor nanostructures 26U would remain free of the upper gap-filling metal 84U.

Additionally, a removal process is performed to level top surfaces of the upper gate electrodes 80U (e.g., the upper gap-filling metal 84U) and the second ILD 72. The removal process may be similar to the removal process described above in connection with forming the gate dielectrics 78. In some embodiments, a planarization process such as a chemical mechanical polish (CMP), an etch-back process, combinations thereof, or the like may be utilized. After the planarization process, the top surfaces of the upper gap-filling metal 84U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” or a “gate stack” 90 (including upper gate structures 90U and lower gate structures 90L). Each gate stack 90 extends along three sides (e.g., a top surface, a sidewall, and a bottom surface) of a channel region of a semiconductor nanostructure 26 (see FIG. 1). The lower gate structures 90L of the gate stacks 90 may also extend along sidewalls and/or a top surface of a semiconductor fin 20'.

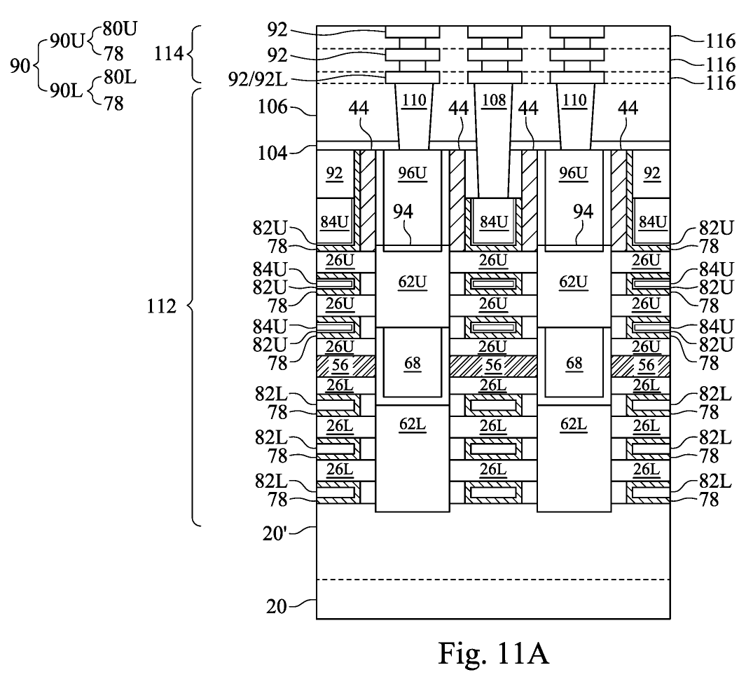

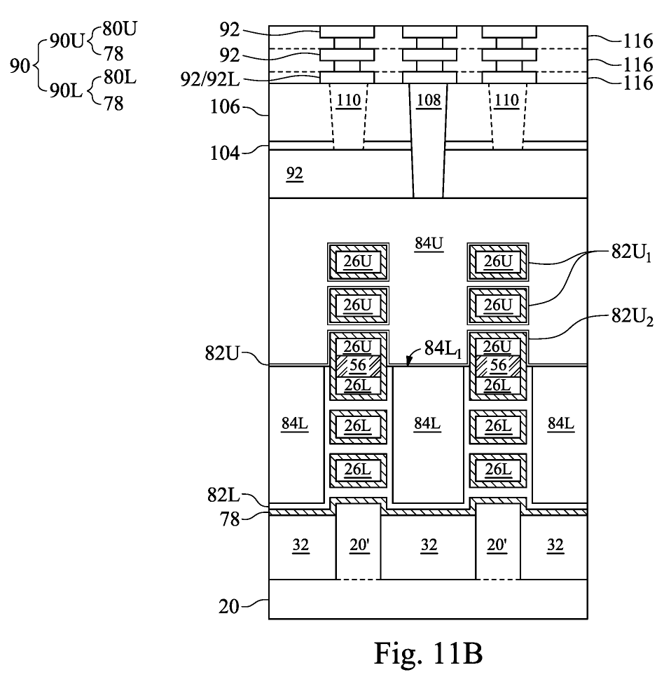

In FIGS. 11A and 11B, gate masks 92 are formed over the gate stacks 90, and metal-semiconductor alloy regions 94 and source/drain contacts 96 are formed through the second ILD 72 to electrically couple to the upper epitaxial source/drain regions 62U and/or the lower epitaxial source/drain regions 62L. For example, the gate stacks 90 may be recessed, and the resulting recesses are filled with a dielectric material such as silicon nitride, silicon carbonitride, silicon oxynitride, silicon oxycarbonitride, the like, or a combination thereof. A planarization process may then be performed to remove the excess portions of the dielectric material over the second ILD 72.

As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate stacks 90L and the lower source/drain regions 62L may be made through a backside of the device layer 112 (e.g., a side opposite to the front-side interconnect structure 114).

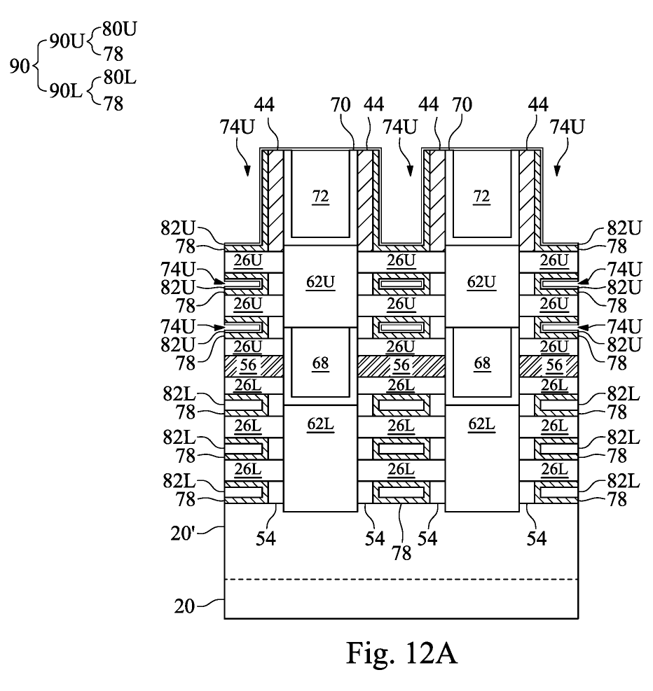

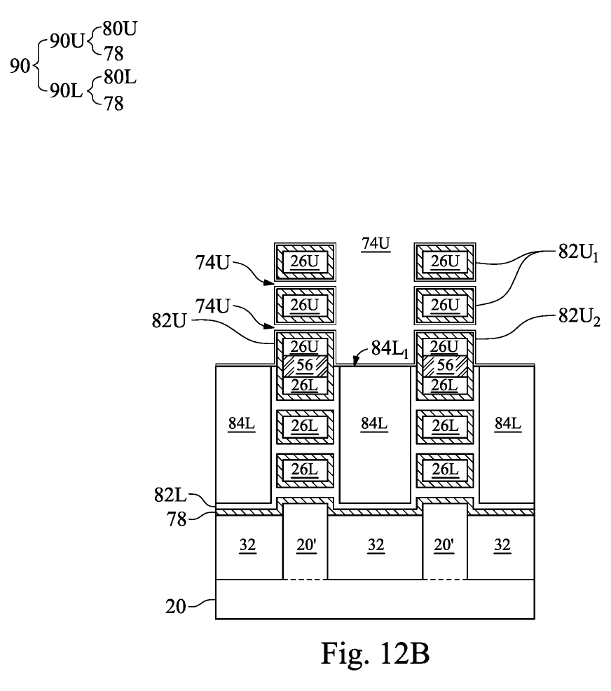

FIGS. 12A-15D illustrate additional embodiments for forming the gate electrodes 80 (e.g., the upper gate electrodes 80U). In particular, before forming the upper gap-filling metal 84U, portions of the upper work function metal layer 82U are etched to expose the upper surface 84L₁ of the lower gap-filling metal 84L of the lower gate electrode 80L. The upper gap-filling metal 84U is then deposited on the exposed upper surface 84L₁ of the lower gap-filling metal 84L which serves as a seed layer for the deposition. In some such embodiments and discussed below, some upper surfaces of the upper work function metal layer 82U are also etched to expose underlying upper surfaces 78U₁ of the gate dielectrics 78.

In FIGS. 12A and 12B, the upper work function metal layer 82U is deposited, similarly as described above in connection with FIGS. 10A and 10B. For example, the upper work function metal layer 82U may comprise titanium aluminum and be deposited by ALD. In addition, the upper work function metal layer 82U may be deposited with a lesser thickness than that of the lower work function metal layer 82L, such as being thin enough for the upper recesses 74U to still include spaces between adjacent upper semiconductor nanostructures 26U. In some embodiments (not specifically illustrated), these spaces may be filled by the upper work function metal layer 82U.

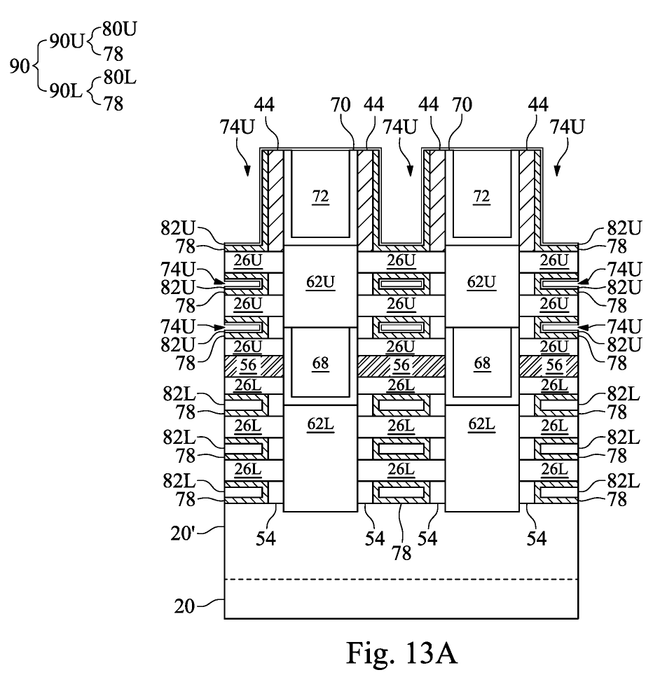

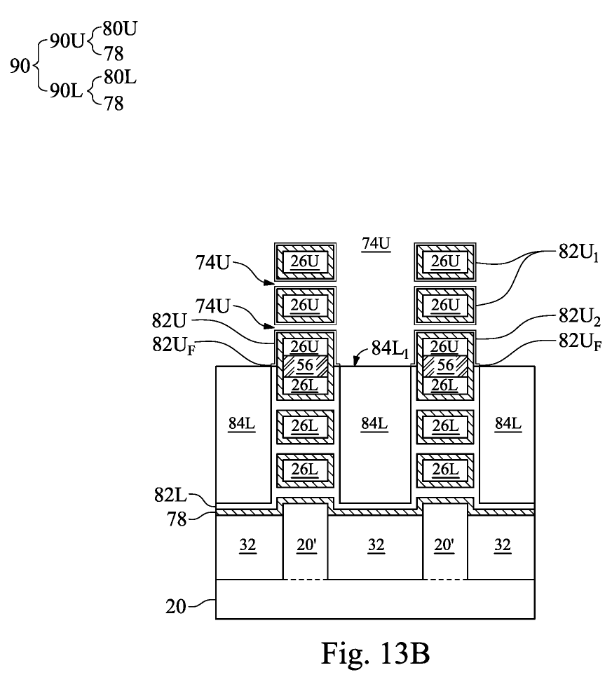

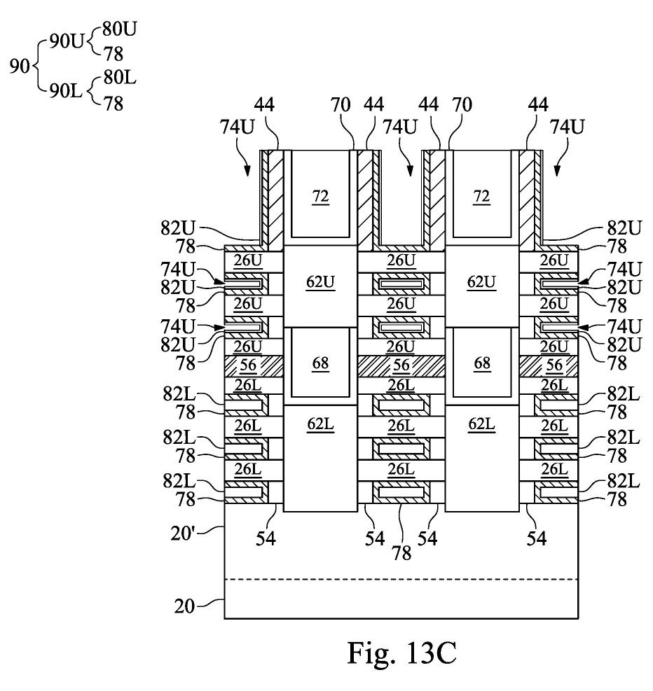

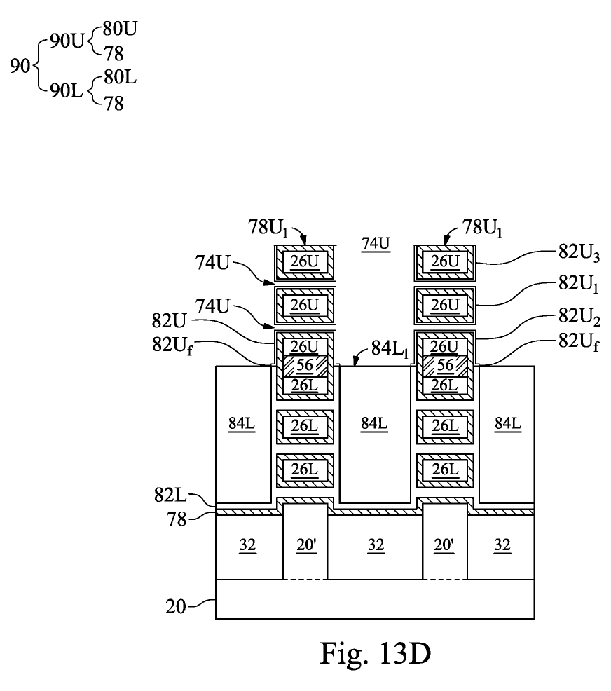

In FIGS. 13A-13D, an etch process is performed to remove portions of the upper work function metal layer 82U to expose an upper surface 84L₁ of the lower gap-filling metal 84L. For example, the etching may be performed by any suitable etch process, such as a Reactive Ion Etch (RIE), Neutral Beam Etch (NBE), the like, or a combination thereof. In addition, the etching may be anisotropic using suitable etchants for the material of the upper work function metal layer 82U (e.g., titanium aluminum).

Referring to FIGS. 13A and 13B, the etch process may be targeted at portions of the upper work function metal layer 82U along an interface with the lower gap-filling metal 84L. In some embodiments, some other portions of the upper work function metal layer 82U may experience some etching due to being exposed to the etchants during the etch process. As such, in some embodiments, certain segments of the upper work function metal layer 82U may be thinned by this process. For example, a thickness of uppermost segments of the upper work function metal layer 82U (e.g., disposed over upper surfaces of uppermost nanostructures of the upper semiconductor nanostructures 26U) after the etch process may be less than the thickness at formation of the upper work function metal layer 82U. In addition, the thickness of the uppermost segments of the upper work function metal layer 82U after the etch process may be less than the thickness of other segments of the upper work function metal layer 82U along the upper semiconductor nanostructures 26U.

Referring to FIGS. 13C and 13D, the etch process may substantially remove the uppermost segments of the upper work function metal layer 82U in addition to the portions along the interface with the lower gap-filling metal 84L. In particular, the above-described thinning of the uppermost segments of the upper work function metal layer 82U may continue until the uppermost segments are removed, thereby exposing upper surfaces 78U₁ of the gate dielectrics 78 along the uppermost nanostructures of the upper semiconductor nanostructures 26U. As a result, in the cross-section illustrated in FIG. 13D, the upper work function metal layer 82U comprises discrete portions around each of the upper semiconductor nanostructures 26U, wherein some of the discrete portions are rings 82U₁ around respective upper semiconductor nanostructures 26U. In addition, some of the discrete portions have U-shapes (e.g., downward U-shaped portions 82U₂) around a lowermost nanostructure of the upper semiconductor nanostructures 26U, and some of the discrete portions have U-shapes (e.g., upward U-shaped portions 82U₃) around the uppermost nanostructures of the upper semiconductor nanostructures 26U.

As further illustrated in FIGS. 13B and 13D, the portions of the etched upper work function metal layer 82U around the lowermost nanostructures of the upper semiconductor nanostructures 26U may have the above-described downward U-shapes, wherein the U-shaped portions 82U₂ have feet 82U_{f} along the lower gate electrodes 80L. In some embodiments, the feet 82U_{f} may extend to the thickness of the lower work function metal layer 82L. In some embodiments (not specifically illustrated), the feet 82U_{f} of the etched portions of the upper work function metal layer 82U may further extend partially over the lower gap-filling metal 84L.

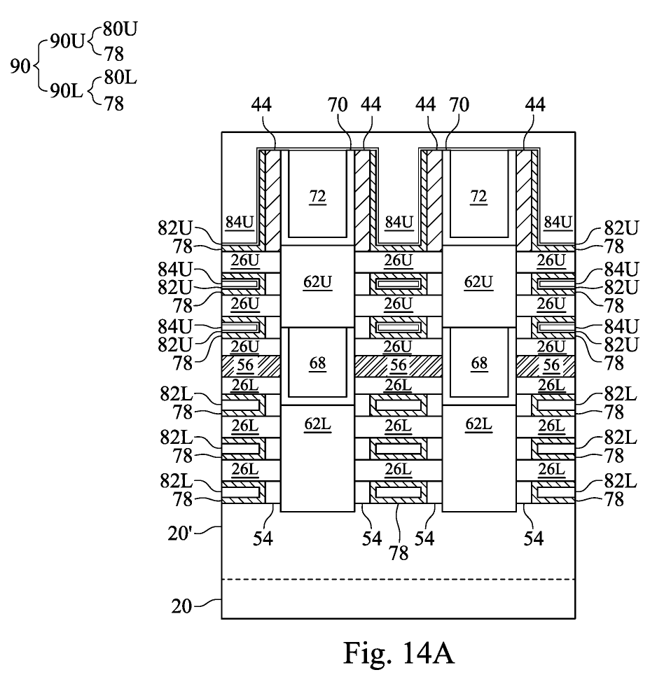

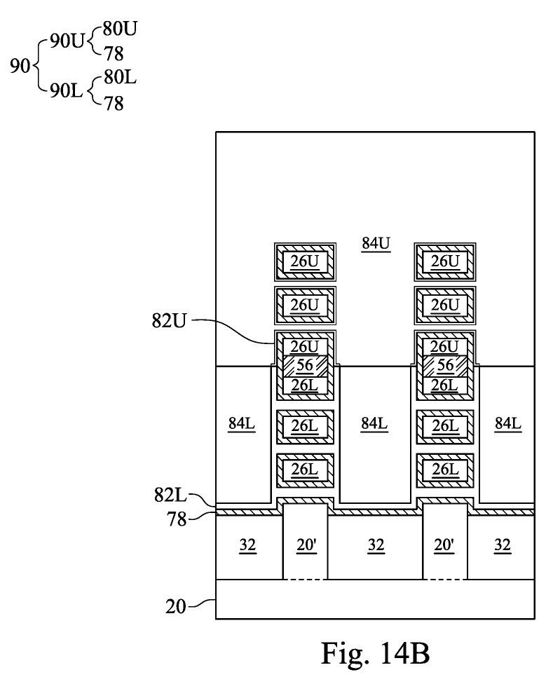

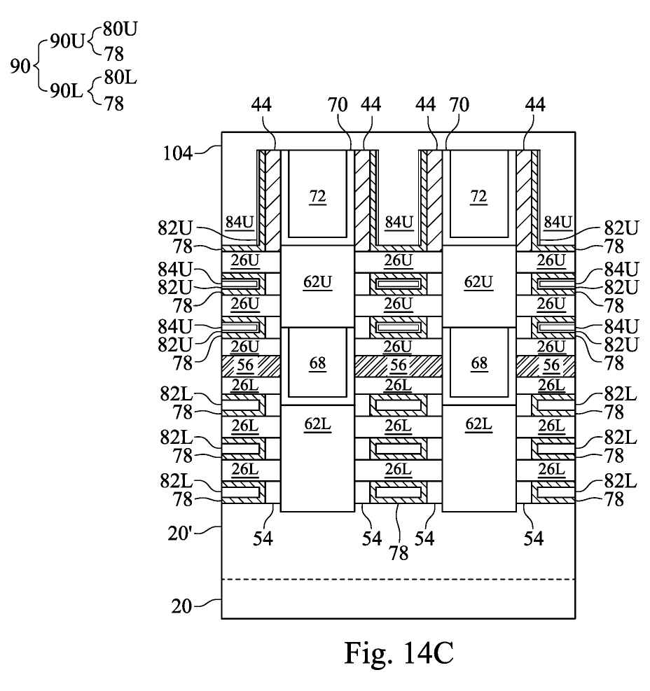

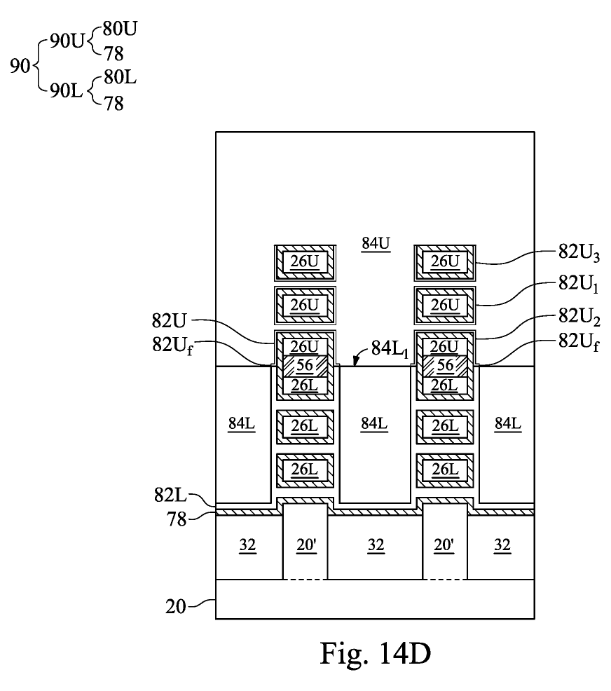

In FIGS. 14A-14D, the upper gap-filling metal 84U is formed over the etched upper work function metal layer 82U of FIGS. 13A-13D, respectively, similarly as described above in connection with FIGS. 10A and 10B, unless as otherwise stated herein. For example, the upper gap-filling metal 84U may be formed of the same candidate materials and candidate processes as described above. In accordance with some embodiments, the upper gap-filling metal 84U may comprise ruthenium and/or molybdenum and be deposited by CVD. For example, the upper gap-filling metal 84U may comprise a same material as the lower gap-filling metal 84L.

As noted above, by etching the upper work function metal layer 82U (see FIGS. 13A-13D), the exposed upper surface 84L₁ of the lower gap-filling metal 84L can serve as a seed layer for deposition of the upper gap-filling metal 84U. As such, formation of the upper gap-filling metal 84U may omit the initial ALD process as described above in connection with FIGS. 10A and 10B. As a result, deposition of the upper gap-filling metal 84U may take less time by having fewer steps. In addition, the upper gap-filling metal 84U may initially grow at a faster rate on the lower gap-filling metal 84L as compared to other exposed surfaces. This may result in a more consistent bottom-up growth behavior which can be better controlled and halted when the upper recesses 74U are filled.

Referring to FIGS. 14A and 14B, the upper gap-filling metal 84U is deposited on exposed surfaces of the lower gap-filling metal 84L and the upper work function metal layer 82U. In addition, the bottom-up growth behavior may be more consistent due to the upper gap-filling metal 84U initially growing faster on the lower gap-filling metal 84L as compared to growth on the upper work function metal layer 82U.

Referring to FIGS. 14C and 14D, the upper gap-filling metal 84U is deposited on exposed surfaces of the lower gap-filling metal 84L, the upper work function metal layer 82U, and also the gate dielectrics 78 along the uppermost nanostructures of the upper semiconductor nanostructures 26U. Similarly as discussed above, the bottom-up growth behavior may be more consistent due to the upper gap-filling metal 84U initially growing faster on the lower gap-filling metal 84L as compared to growth on the exposed surfaces of the gate dielectrics 78.

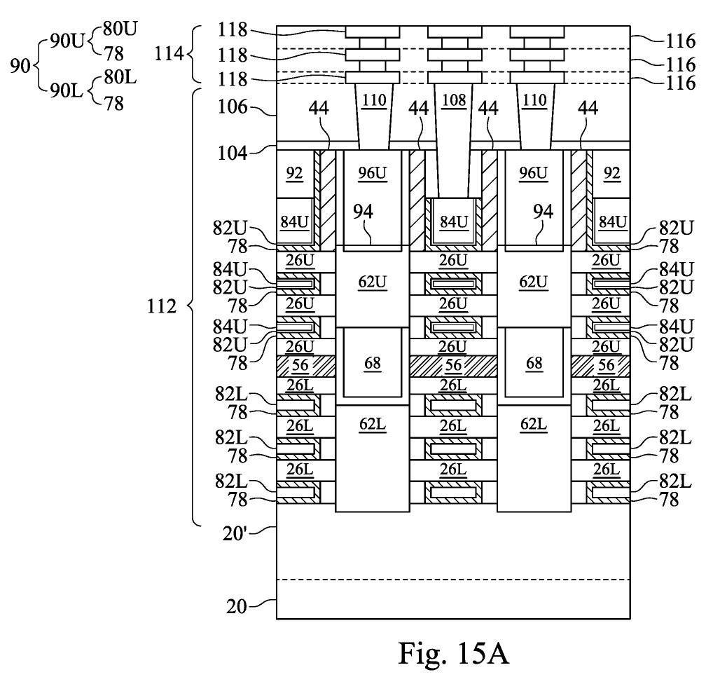

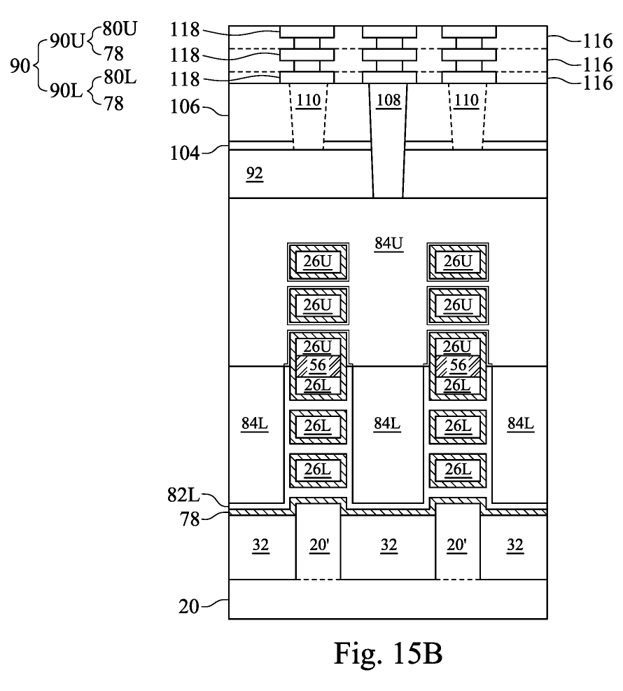

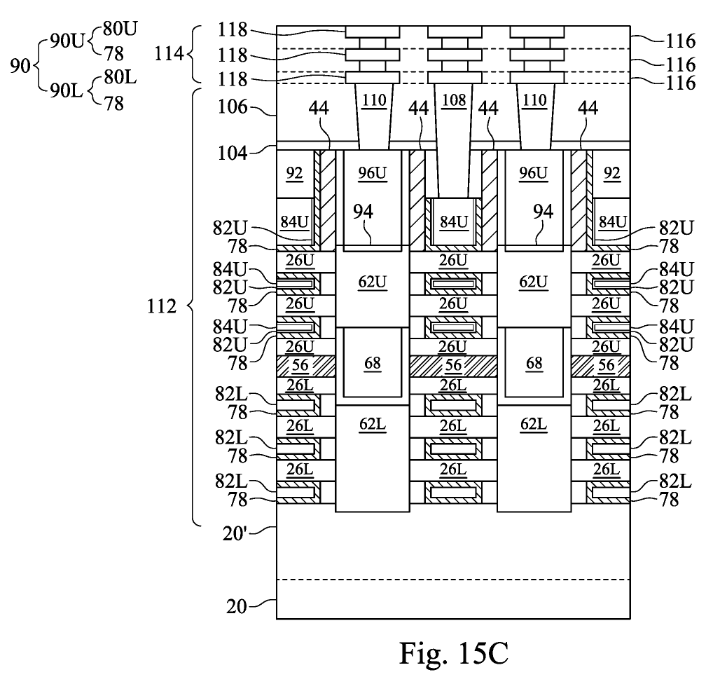

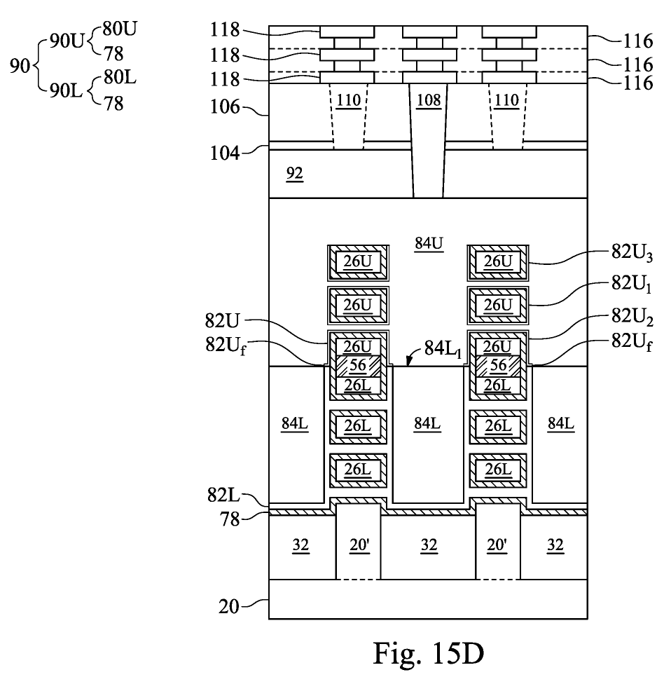

In FIGS. 15A-15D, source/drain contacts 96, gate contacts 108, source/drain vias 110, and a front-side interconnect structure 114 are formed over the structures of FIGS. 14A-14D, respectively, similarly as described above in connection with FIGS. 11A and 11B. Note that the processing steps include any steps and features described above as applicable to these embodiments.

Various advantages are achieved. The disclosed embodiments may be utilized to form a stacking transistor structure comprising a gate stack 90 with a lower gate electrode 80L and an upper gate electrode 80U. In particular, the lower gate electrode 80L and the upper gate electrode 80U may comprise differing materials. A recess 74 is formed as the location of both the lower and the upper gate electrodes 80L and 80U. The lower gate electrode 80L is first formed by using ALD to deposit a lower work function metal layer 82L (e.g., comprising titanium nitride) and using CVD to deposit a lower gap-filling metal 84L (e.g., comprising ruthenium or molybdenum) to fill the recess 74. These processes and materials allow the material of the lower gate electrode 80L to be deposited as substantially free of seams. These materials are then etched to open an upper portion of the recess 74 for the upper gate electrode 80U (e.g., the upper recess 74U). The etch process can be performed with greater control and improved yield due to the lower gate electrode 80L lacking seams. The upper gate electrode 80U may then be formed over the etched lower gate electrode 80L. The stacking transistor structure may therefore be formed at greater yield and function with improved performance and reliability.

In an embodiment, a method includes forming a lower source/drain region and an upper source/drain region adjacent to a multi-layer stack, the multi-layer stack comprising dummy nanostructures that are alternatingly stacked with semiconductor nanostructures, the semiconductor nanostructures comprising lower semiconductor nanostructures and upper semiconductor nanostructures; removing the dummy nanostructures; forming first gate dielectrics around each of the lower semiconductor nanostructures and second gate dielectrics around each of the upper semiconductor nanostructures; forming a first work function metal layer over the first gate dielectrics and the second gate dielectrics; forming a first gap-filling metal over the first work function metal layer; performing a first etch process on the first gap-filling metal to expose the first work function metal layer; performing a second etch process on the first work function metal layer to expose the second gate dielectrics; forming a second work function metal layer over the second gate dielectrics; and forming a second gap-filling metal over the second work function metal layer. In another embodiment, forming the first work function metal layer comprises atomic layer deposition, and wherein forming the first gap-filling metal comprises chemical vapor deposition. In another embodiment, the first work function metal layer comprises titanium nitride, and wherein the first gap-filling metal comprises ruthenium. In another embodiment, the second work function metal layer comprises titanium aluminum, and wherein the second gap-filling metal comprises titanium nitride. In another embodiment, the second work function metal layer comprises titanium aluminum, and wherein the second gap-filling metal comprises ruthenium. In another embodiment, in a cross-section the first work function metal layer comprises a plurality of first portions, wherein each first portion is disposed around a respective nanostructure of the lower semiconductor nanostructures, and wherein the first portions are continuous with one another. In another embodiment, in the cross-section the second work function metal layer comprises a plurality of second portions, wherein each second portion is disposed around a respective nanostructure of the upper semiconductor nanostructures, and wherein the second portions are discrete from one another.

In an embodiment, a method includes forming a first semiconductor nanostructure over a substrate; forming a second semiconductor nanostructure over the first semiconductor nanostructure; depositing a p-type work function metal layer over the first semiconductor nanostructure and the second semiconductor nanostructure; depositing a first fill metal structure over the p-type work function metal layer, wherein the first fill metal structure is ruthenium or molybdenum; performing a first etch process on the first fill metal structure; performing a second etch process on the p-type work function metal layer; after performing the first etch process and the second etch process, depositing an n-type work function metal layer over the first fill metal structure; and depositing a second fill metal structure over the n-type work function metal layer. In another embodiment, the p-type work function metal layer comprises titanium nitride, and wherein the second fill metal structure comprises titanium nitride. In another embodiment, the second fill metal structure is a same material as the first fill metal structure. In another embodiment, the method further includes, before depositing the second fill metal structure, performing a third etch process on the n-type work function metal layer. In another embodiment, performing the third etch process comprises exposing an upper surface of the first fill metal structure. In another embodiment, the third etch process comprises an anisotropic etch.

In an embodiment, a semiconductor device includes a multi-layer stack comprising: a first nanostructure over a substrate; a second nanostructure over the first nanostructure; and a dielectric isolation layer between the first nanostructure and the second nanostructure; a first gate structure over and around a portion of the first nanostructure, the first gate structure comprising: a first gate dielectric layer over the first nanostructure; a first work function metal layer over the first gate dielectric layer; and a first metal over the first work function metal layer; and a second gate structure over and around a portion of the second nanostructure, the second gate structure comprising: the first gate dielectric layer over the second nanostructure, the first gate dielectric layer comprising a continuous ring around the first nanostructure, the second nanostructure, and the dielectric isolation layer; a second work function metal layer over the first gate dielectric layer, the second work function metal layer interfacing with the first work function metal layer; and a second metal over the second work function metal layer. In another embodiment, a portion of the second work function metal layer is interposed between the first metal and the second metal. In another embodiment, the first work function metal layer comprises titanium nitride, wherein the first metal comprises ruthenium, wherein the second work function metal layer comprises titanium aluminum, and wherein the second metal comprises titanium nitride. In another embodiment, the first metal interfaces with the second metal. In another embodiment, the first work function metal layer comprises titanium nitride, wherein the first metal comprises ruthenium, wherein the second work function metal layer comprises titanium aluminum, and wherein the second metal comprises ruthenium. In another embodiment, the semiconductor device further includes a third nanostructure over the second nanostructure; a second gate dielectric layer around the third nanostructure; and a third work function metal layer around the second gate dielectric layer, wherein the second metal is disposed between the second nanostructure and the third nanostructure. In another embodiment, the semiconductor device further includes a fourth nanostructure between the substrate and the first nanostructure; a third gate dielectric layer around the fourth nanostructure; and a fourth work function metal layer around the third gate dielectric layer, wherein the first work function metal layer interfaces with the fourth work function metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming gate dielectrics around lower semiconductor nanostructures and around upper semiconductor nanostructures, the upper semiconductor nanostructures over the lower semiconductor nanostructures;
forming a lower gate electrode around the lower semiconductor nanostructures, the lower gate electrode comprising a lower work function metal layer over the gate dielectrics and a lower fill metal over the lower work function metal layer;
forming an upper work function metal layer over the gate dielectrics around the upper semiconductor nanostructures;
etching the upper work function metal layer to expose an upper surface of the lower fill metal; and
forming an upper fill metal on the exposed upper surface of the lower fill metal and on the upper work function metal layer, the upper surface of the lower fill metal serving as a seed for growth of the upper fill metal.

2. The method of claim 1, wherein forming the upper fill metal comprises depositing the upper fill metal by chemical vapor deposition without forming a separate seed layer.

3. The method of claim 1, wherein the upper fill metal grows at a faster rate on the exposed upper surface of the lower fill metal than on the upper work function metal layer.

4. The method of claim 1, wherein the lower fill metal comprises ruthenium or molybdenum.

5. The method of claim 4, wherein the upper fill metal comprises a same material as the lower fill metal.

6. The method of claim 1, wherein etching the upper work function metal layer further exposes an upper surface of the gate dielectrics along an uppermost nanostructure of the upper semiconductor nanostructures, and the upper fill metal is formed on the upper surface of the gate dielectrics.

7. The method of claim 1, wherein forming the lower gate electrode comprises depositing the lower fill metal with a bottom-up growth behavior such that the lower fill metal is free of a vertical seam.

8. A method comprising:
forming a lower work function metal layer over gate dielectrics around lower semiconductor nanostructures and around upper semiconductor nanostructures, the upper semiconductor nanostructures over the lower semiconductor nanostructures;
forming a fill metal over the lower work function metal layer around the lower semiconductor nanostructures and around the upper semiconductor nanostructures;
performing a first etch process to remove the fill metal from around the upper semiconductor nanostructures, the first etch process removing the fill metal at a faster rate than the lower work function metal layer, the first etch process exposing the lower work function metal layer around the upper semiconductor nanostructures such that the exposed lower work function metal layer protects the fill metal around the lower semiconductor nanostructures;
performing a second etch process to remove the lower work function metal layer from around the upper semiconductor nanostructures, the second etch process removing the lower work function metal layer at a faster rate than the fill metal around the lower semiconductor nanostructures; and
forming an upper gate electrode around the upper semiconductor nanostructures.

9. The method of claim 8, wherein the first etch process comprises a dry etch process and the second etch process comprises a wet etch process.

10. The method of claim 8, wherein the fill metal comprises ruthenium or molybdenum, and the lower work function metal layer comprises titanium nitride.

11. The method of claim 8, wherein forming the fill metal comprises depositing the fill metal with a bottom-up growth behavior such that the fill metal is free of a vertical seam.

12. The method of claim 8, wherein the first etch process removes the fill metal from around the upper semiconductor nanostructures until an upper surface of the fill metal is laterally adjacent to a dielectric isolation layer between the lower semiconductor nanostructures and the upper semiconductor nanostructures.

13. The method of claim 8, wherein forming the upper gate electrode comprises forming an upper work function metal layer over the gate dielectrics around the upper semiconductor nanostructures and forming an upper fill metal over the upper work function metal layer.

14. The method of claim 8, wherein the lower work function metal layer comprises rings around the lower semiconductor nanostructures, and the second etch process converts some of the rings into U-shaped portions.

15. A semiconductor device comprising:
lower semiconductor nanostructures;
upper semiconductor nanostructures over the lower semiconductor nanostructures;
a dielectric isolation layer between the lower semiconductor nanostructures and the upper semiconductor nanostructures;
gate dielectrics around the lower semiconductor nanostructures and around the upper semiconductor nanostructures;
a lower gate electrode around the lower semiconductor nanostructures, the lower gate electrode comprising a lower work function metal layer over the gate dielectrics and a lower gap-filling metal over the lower work function metal layer, the lower work function metal layer comprising rings around the lower semiconductor nanostructures that are continuous with one another; and
an upper gate electrode around the upper semiconductor nanostructures, the upper gate electrode comprising an upper work function metal layer over the gate dielectrics and an upper gap-filling metal, the upper work function metal layer comprising discrete portions around the upper semiconductor nanostructures, a portion of the upper work function metal layer being between the lower gap-filling metal and the upper gap-filling metal.

16. The semiconductor device of claim 15, wherein the lower gap-filling metal comprises ruthenium or molybdenum.

17. The semiconductor device of claim 16, wherein the upper gap-filling metal comprises a same material as the lower gap-filling metal.

18. The semiconductor device of claim 15, wherein the upper work function metal layer comprises a ring around a first nanostructure of the upper semiconductor nanostructures and a downward U-shaped portion around a lowermost nanostructure of the upper semiconductor nanostructures, the downward U-shaped portion having a foot along the lower gate electrode.

19. The semiconductor device of claim 15, wherein the upper work function metal layer comprises an upward U-shaped portion around an uppermost nanostructure of the upper semiconductor nanostructures, and an upper surface of the gate dielectrics along the uppermost nanostructure is free of the upper work function metal layer.

20. The semiconductor device of claim 15, wherein the lower gap-filling metal is free of a vertical seam.
